(19) United States
(12) Patent Application Publication
(10) Pub. No.: US 2009/0115510 A1
(43) Pub. Date: May 7, 2009

(54) DEVICE FOR AMPLIFYING A VOLTAGE REPRESENTING AN AUDIOPHONIC INFORMATION

(75) Inventor: Vincent Tamisier, Laval (FR)

Correspondence Address: YOUNG & THOMPSON, 209 Madison Street, Suite 500, ALEXANDRIA, VA, 22314, US

(73) Assignee: Storm Audio, Laval (FR)

(21) Appl. No.: 12/066,082

(22) PCT Filed: Sep. 6, 2006
(86) PCT No.: PCT/FR2006/002056

§ 371 Date: Sep. 3, 2008

(30) Foreign Application Priority Data
Sep. 7, 2005 (FR) 0509131

(51) Int. Cl. H03F 3/38

(52) U.S. Cl. 330/10

(57) ABSTRACT

The invention concerns a device (10) for amplifying a voltage (Ve) representing a sound amplifying information derived for a source (12) for driving a load (14), the device comprising a class D amplifying chain (16) adapted to deliver at least one load driving amplified electric signal (Vs) based on the voltage representing the acoustic information. Said device comprises means (44) for measuring at least one current of the amplifying chain, and one first loop for correcting (46) at least one electric signal based on the measurement of the or each current.

The present invention relates to a device for amplifying a voltage representing an audiophonic information from a source in order to drive an acoustic load.

More specifically, the present invention relates to such a device comprising a class D amplifying chain intended to deliver at least one amplified electrical signal for driving the load as a function of the voltage representing the audiophonic information.

Such devices used in mass-produced equipments, such as mobile phones, for example, are known. Typically, the sound quality is generally not very satisfactory because of the small passband of these amplification devices.

The aim of the present invention is to solve the above-mentioned problem.

To this end, a subject-matter of the invention is a power amplifying device for amplifying a voltage representing an audiophonic information from a source in order to drive an acoustic load, the device comprising a class D amplifying chain intended to deliver at least one amplified electrical signal for driving the load as a function of the voltage representing the acoustic information, characterized in that it additionally comprises:
means for measuring at least one current in the amplifying chain; and
a first correction loop for correcting the or each electrical signal as a function of the measurement of the or each current.

According to particular embodiments, the device includes one or more of the following features:
the first correction loop comprises:
   means for converting the measured current into a measurement voltage; and
   means for correcting a voltage delivered at the input of the amplifying chain as a function of the measurement voltage;
the correction means comprise means of control of the measurement voltage on the voltage delivered at the input of the amplifying chain;
the amplifying chain comprises a class D power amplifier and at least one low-pass filter arranged at the output of the amplifier, and the measurement means are intended to measure the current at the output of the or each low-pass filter;
the amplifying chain comprises a class D power amplifier and at least one low-pass filter arranged at the output of the amplifier, and the measurement means are intended to measure the current at the input of the or each low-pass filter;
the measurement means are chosen to have a frequency behaviour substantially equal to that of the or each low-pass filter;
the amplifying chain comprises an amplifier of a type having a half-bridge setup;
the amplifying chain comprises an amplifier of a type having an H-bridge setup;
the measurement means are intended to measure only one current flowing in the amplifying chain;
the measurement means are intended to measure two currents flowing in the amplifying chain;
the conversion means comprise subtraction means for the two measured currents and means for transforming the subtracted currents into the measurement voltage;
it additionally comprises:
   means for measuring at least one voltage in the amplifying chain; and
   a second correction loop, outside the first correction loop, adapted to correct the amplified electrical signal as a function of the or each measured voltage;
the second correction loop comprises means of control of the or each measured voltage on the voltage representing the audiophonic information;
the amplifying chain comprises a class D power amplifier and at least one low-pass filter arranged at the output of the amplifier, and the means for measuring the or each voltage are intended to measure the voltage at the output of the or each low-pass filter;
the amplifying chain comprises a class D power amplifier and at least one low-pass filter arranged at the output of the amplifier, and the means for measuring the or each voltage are intended to measure the voltage at the input of the or each low-pass filter;
the means for measuring the at least one voltage are intended to measure only one voltage in the amplifying chain;
the means for measuring the or each voltage are intended to measure the difference between two voltages in the amplifying chain, and the outer second correction loop comprises means for correcting a voltage delivered at the input of the first correction loop as a function of the difference between these two voltages.

The invention will be better understood on reading the following description given purely by way of example and with reference to the appended drawings in which identical references denote identical or similar items, and in which:

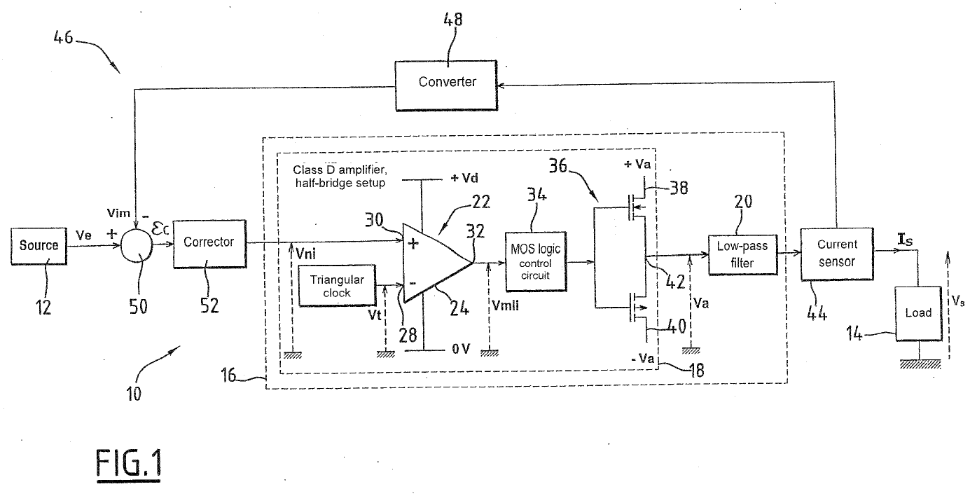

FIG. 1 is a schematic view of a first embodiment of the device according to the invention;

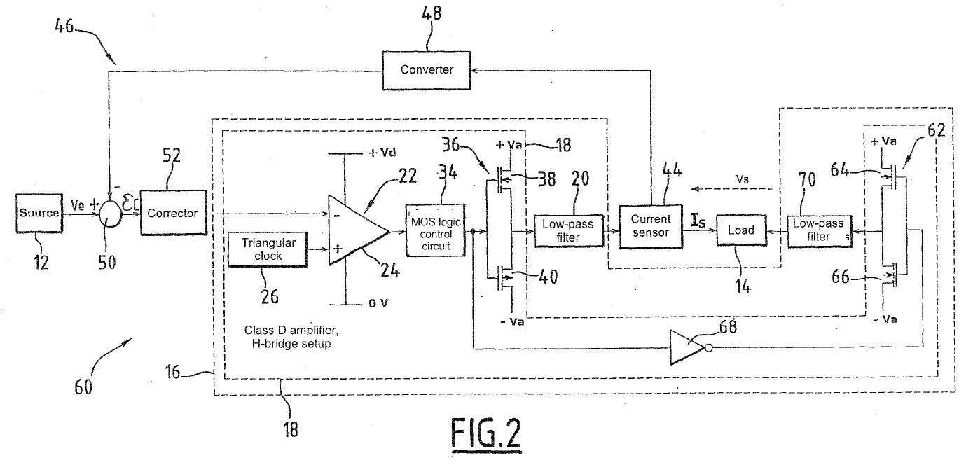

FIG. 2 is a schematic view of a second embodiment of the device according to the invention;

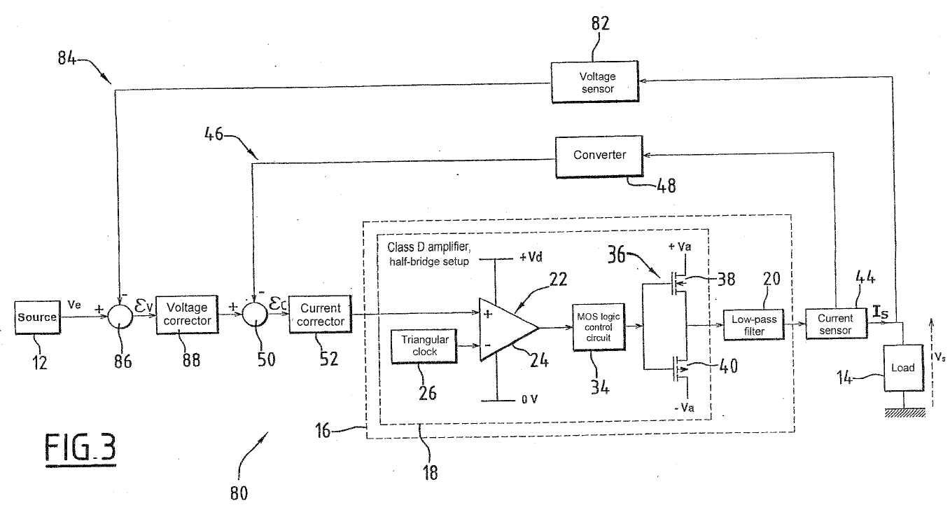

FIG. 3 is a schematic view of a third embodiment of the device according to the invention; and

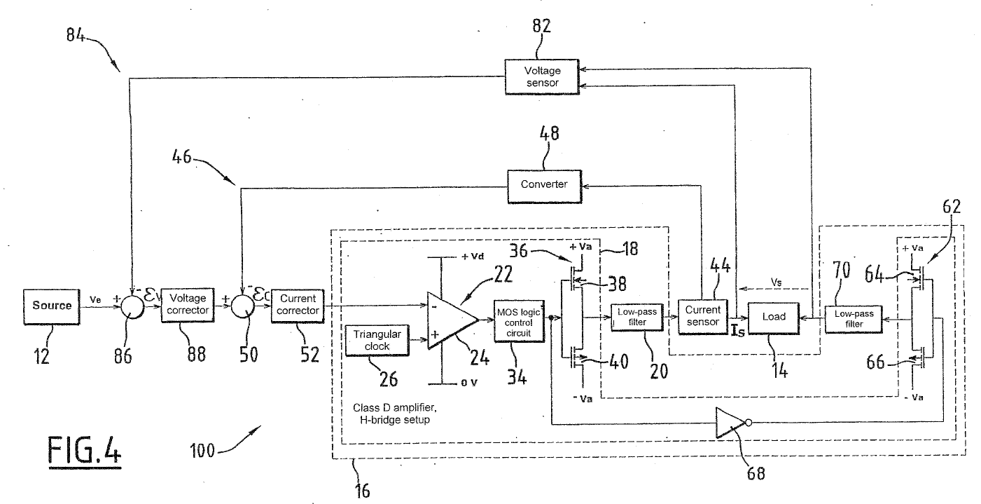

FIG. 4 is a schematic view of a fourth embodiment.

In FIG. 1, there is illustrated under the general reference 10 a first embodiment of a device for amplifying an analogue voltage Ve representing an audiophonic information and delivered by a source 12, such as for example a music CD-ROM player, a microphone, a mobile phone antenna or other. The device 10 drives an electro-mechano-acoustic load 14, such as a loudspeaker, using the amplified voltage.

To this end, the device 10 comprises an amplifying chain 16 including a class D amplifier 18 of the type having a half-bridge setup in series with a low-pass filter 20.

The amplifier 18 comprises a pulse-width modulation (PWM) modulator 22 formed by a comparator 24 connected to a clock 26 delivering to an inverting terminal 28 of the comparator a triangular voltage Vt of predetermined frequency and amplitude.

The modulator 22 pulse-width-modulates an analogue voltage Vni that the comparator 24 receives at a non-inverting terminal 30 and thus generates at an output 32 of the comparator 24 a pulse-width modulated voltage Vmli, as is known per se.

The amplifier 18 also comprises a logic control circuit 34 connected to the output 32 of the comparator 24 and controlling as a function of the voltage Vmli a half-bridge setup 36 formed by an n-channel MOSFET transistor 38 and a p-channel MOSFET transistor 40 with a common source, as is known per se. The half-bridge setup 36 thus delivers at an output 42 an amplification of the voltage Vni in the form of an amplified voltage Va.

Lastly, the amplifier 18 is connected to an electric switched-mode power supply (not represented) to supply electrical power to these components.

The low-pass filter 20, for example formed by an LC circuit, is connected to the output 42 of the half-bridge setup 36 and delivers as output an average Vs of the amplified voltage Va. The load 14 is connected at one of its terminals to the output of the low-pass filter 20 and at the other of its terminals to ground.

The device 10 additionally comprises a current sensor 44 arranged at the output of the low-pass filter 20, for example a current sensor based on transistors of the MAX47ESA type of the company Maxim Integrated Products Inc.

The current sensor 44 measures the current Is at the output of the low-pass filter and a correction loop 46 is connected for correcting the voltage Vs driving the load 14.

This loop 46 is a feedback loop comprising a current/voltage converter 48 connected to the current sensor 44 and generating a measurement voltage Vim that is an image of the current Is measured by the current sensor 44. For example, the converter 46 is formed by a resistance of predetermined impedance.

As a variant, the current sensor and the current/voltage converter are formed by a resistance of predetermined impedance arranged in series with the low-pass filter 20 and at the output of the latter and by a voltage sensor measuring the voltage across the terminals of said resistance.

The correction loop 46 also comprises a subtractor 50 and a corrector 52. The subtractor 50 is connected to the converter 48 and to the source 12, and delivers as output the difference εc between these two voltages, hereafter referred to as a “current control error”.

The corrector 52 is connected to the output of the subtractor 50 and determines as a function of the control error εc the analogue voltage Vni. The corrector 52 implements a predetermined law of control of the measurement voltage Vim on the voltage Ve, such as for example a proportional-integral (PI) law or a proportional-integral-derivative (PID) law, having the effect of substantially cancelling out the control error εc and resulting in the stability and performance conditions required for the correction loop.

The corrector 52 is implemented in the form of an analogue circuit, or as a variant it comprises a digital signal processing unit, such as a DSP processor for example.

As a variant, the current sensor 44 is arranged between the amplifier 18 and the low-pass filter 20 and its passband is chosen to be substantially equal to that of the low-pass filter 20. More specifically, it is known that the current sensor 44 behaves substantially like a low-pass filter and the current sensor 44 is chosen in order that its frequency behaviour is substantially equal to that of the low-pass filter 20. In particular, the cut-off frequency of the sensor 44 is chosen so as not to differ from that of the filter 20 by more than 10 percent.

As a variant, the corrector 52 is arranged between the converter 48 and the subtractor 50.

As a variant, the transistors 38, 40 of the half-bridge setup are insulated gate bipolar transistors (IGBTs) when high signal power levels are required.

As a variant, the low-pass filter 20 is omitted.

In FIG. 2, there is illustrated under the general reference 60 a second embodiment of the device according to the invention. This second embodiment differs from that of FIG. 1 mainly in that the transistors setup 36 of the amplifier 18 is an H-bridge setup which ensures electrical symmetry and that of the signals of the entire device.

In this embodiment, the amplifier 36 comprises two half-bridge setups 36, 62 each formed by an n-channel MOSFET transistor 38, 64 and a p-channel MOSFET transistor 40, 66 with a common source. These setups 36, 62 are identical to that of FIG. 1. A first setup 36 is connected directly to the output of the control logic circuit 34 and a second setup is connected to the latter via an inverter 68.

Lastly, a low-pass filter 20, 70 is connected to the output of each setup 36, 62. These low-pass filters are identical to the low-pass filter of FIG. 1 and deliver averaged voltages to the load 14 which is thus driven symmetrically.

As a variant, the device which has just been described comprises two current sensors that are identical to the sensor 44 and arranged at the outputs of the low-pass filters 20, 70. The correction loop 46 then comprises, arranged between the two current sensors and the current/voltage converter 48, a circuit forming the difference between the two measured currents, dividing this difference by 2 and transforming the result of this operation into the measurement voltage. Such a circuit therefore averages the drive current Is and filters out parasitic noise.

As a variant, the current sensor or sensors are arranged at the inputs of the low-pass filters and each current sensor is chosen to have a frequency behaviour substantially equal to that of the low-pass filters, as described previously.

As a variant the low-pass filters 20, 70 are omitted.

It is to be noted that the correction loops described above are based on a measurement of one or two currents in the amplifying chains, and that the correction is performed as a function of a signal that is an image of the measured current or currents, and this is not equivalent, particularly in terms of impedance, to a correction loop based on a measurement of one or more voltages in the amplifying chain.

It is thus observed that these correction loops have the effect of substantially increasing the passband of the amplifying chains and substantially improving the overall stability and precision of the amplification.

FIG. 3 is a schematic view of a third embodiment of the device according to the invention. Denoted by the general reference 80, this device has all the items of that of FIG. 1 as well as a voltage sensor 82 measuring the voltage Vs at the output of the low-pass filter 20 and an additional correction loop 84.

The additional correction loop 84 is a feedback loop correcting the measured voltage Vs. The loop 84 is outside the correction loop 46 and includes a second subtractor 86 and a second corrector 88 connected to the output of the second subtractor 86.

The second subtractor 86 is connected to the source 12 and to the voltage sensor 82 and forms the difference between the voltage Ve and the measured voltage Vs, this difference Pv hereafter referred to as a “voltage control error”.

The second corrector 88 determines, as a function of the voltage control error Ev, the analogue voltage at the input of the subtractor 50 of the inner correction loop 46, as illustrated in FIG. 3. The second corrector 88 implements a predetermined law of control of the voltage Vs on the voltage Ve, such as for example a proportional-integral (PI) law or a proportional-integral-derivative (PID) law, having the effect of substantially cancelling out the voltage control error Ev and resulting in the stability and performance conditions required for the correction loop.

The second corrector 88 is implemented in the form of an analogue circuit, or as a variant it comprises a digital signal processing unit, such as a DSP processor for example.

Just as for the current sensor or sensors, as a variant, the voltage sensor measures the voltage at the input of the low-pass filter 20 and is chosen to have a frequency behaviour substantially equal to that of the low-pass filter.

Also as a variant, the second corrector 88 is arranged between the voltage sensor 82 and the second subtractor 86.

FIG. 4 is a schematic view of a fourth embodiment 100 of the device according to the invention.

This embodiment comprises all the items of the embodiment of FIG. 2 as well as a voltage sensor 48 and a second correction loop 84 which are similar to the voltage sensor 48 and the second correction loop 84 of the device of FIG. 3.

The voltage sensor 48 of the fourth embodiment nevertheless differs from that of the third embodiment in that it measures the difference between the voltages at the outputs of the low-pass filters 20, 70, i.e. the voltage across the terminals of the load 14.

As a variant, the voltage sensor 48 of the fourth embodiment is identical to that of the third embodiment and measures the voltage at the output of the bandpass filter 20.

As a variant, the voltage sensor of the fourth embodiment measures the difference between the voltages at the inputs of the low-pass filters 20, 70 and is chosen to have a frequency behaviour substantially equal to those of the low-pass filters 20, 70.

Also as a variant, the second corrector 88 is arranged between the voltage sensor 82 and the second subtractor 86.

It is observed that the outer loop further improves the stability and precision of the amplification.

1. A device (10; 60; 80; 100) for amplifying a voltage (Ve) representing an audiophonic information from a source (12) in order to drive a load (14), the device comprising a class D amplifying chain (16) intended to deliver at least one amplified electrical signal (Vs) for driving the load as a function of the voltage representing the acoustic information, characterized in that it additionally comprises:
means (44) for measuring at least one current in the amplifying chain; and
a first correction loop (46) for correcting the or each electrical signal as a function of the measurement of the or each current.

2. A device according to claim 1, characterized in that the first correction loop comprises:
means (48) for converting the measured current into a measurement voltage; and
means (50, 52) for correcting a voltage delivered at the input of the amplifying chain as a function of the measurement voltage.

3. A device according to claim 2, characterized in that the correction means (50, 52) comprise means of control of the measurement voltage on the voltage delivered at the input of the amplifying chain.

4. A device according to claim 1, characterized in that the amplifying chain (16) comprises a class D power amplifier (18) and at least one low-pass filter (20, 70) arranged at the output of the amplifier (18), and in that the measurement means (44) are intended to measure the current at the output of the or each low-pass filter.

5. A device according to claim 1, characterized in that the amplifying chain (16) comprises a class D power amplifier (18) and at least one low-pass filter (20, 70) arranged at the output of the amplifier, and in that the measurement means (44) are intended to measure the current at the input of the or each low-pass filter.

6. A device according to claim 5, characterized in that the measurement means (44) are chosen to have a frequency behaviour substantially equal to that of the or each low-pass filter (20, 70).

7. A device according to claim 2, characterized in that the amplifying chain (16) comprises an amplifier (18) of a type having a half-bridge setup.

8. A device according to claim 1, characterized in that the amplifying chain (16) comprises an amplifier (18) of a type having an H-bridge setup.

9. A device according to claim 7, characterized in that the measurement means (44) are intended to measure only one current flowing in the amplifying chain (16).

10. A device according to claim 8, characterized in that the measurement means (44) are intended to measure two currents flowing in the amplifying chain (16).

11. A device according to claim 10, characterized in that the conversion means (48) comprise subtraction means for the two measured currents and means for transforming the subtracted currents into the measurement voltage.

12. A device according to claim 1, characterized in that it additionally comprises:
means (82) for measuring at least one voltage in the amplifying chain; and
a second correction loop (84), outside the first correction loop (46), adapted to correct the amplified electrical signal as a function of the or each measured voltage.

13. A device according to claim 12, characterized in that the second correction loop (84) comprises means (86, 88) of control of the or each measured voltage on the voltage representing the audiophonic information.

14. A device according to claim 12, characterized in that the amplifying chain (16) comprises a class D power amplifier (18) and at least one low-pass filter (20, 70) arranged at the output of the amplifier (18), and in that the means (82) for measuring the or each voltage are intended to measure the voltage at the output of the or each low-pass filter (20, 70).

15. A device according to claim 12, characterized in that the amplifying chain (16) comprises a class D power amplifier (18) and at least one low-pass filter (20, 70) arranged at the output of the amplifier (18), and in that the means (82) for measuring the or each voltage are intended to measure the voltage at the input of the or each low-pass filter (20, 70).

16. A device according to claim 12, characterized in that the means (82) for measuring the at least one voltage are intended to measure only one voltage in the amplifying chain (16).

17. A device according to claim 12, wherein the measurement means (44) are arranged to measure only one current flowing in the amplifying chain 16, and the means (82) for measuring the or each voltage are intended to measure the difference between two voltages in the amplifying chain (16), and in that the outer second correction loop comprises means (86, 88) for correcting a voltage delivered at the input of the first correction loop (46) as a function of the difference between these two voltages.

18. A device according to claim 1, characterized in that the amplifying chain (16) comprises an amplifier (18) of a type having a half-bridge setup.

19. A device according to claim 13, characterized in that the amplifying chain (16) comprises a class D power amplifier (18) and at least one low-pass filter (20, 70) arranged at the output of the amplifier (18), and in that the means (82) for measuring the or each voltage are intended to measure the voltage at the output of the or each low-pass filter (20, 70).

20. A device according to claim 13, characterized in that the amplifying chain (16) comprises a class D power amplifier (18) and at least one low-pass filter (20, 70) arranged at the output of the amplifier (18), and in that the means (82) for measuring the or each voltage are intended to measure the voltage at the input of the or each low-pass filter (20, 70).
